(19) United States
(12) Patent Application Publication
(10) Pub. No.: US 2026/0173406 A1
(43) Pub. Date: Jun. 18, 2026

(54) MEMORY DEVICE, FORMING METHOD THEREOF, AND MEMORY SYSTEM

(71) Applicant: Yangtze Memory Technologies Co., Ltd., Wuhan (CN)

(72) Inventors: Jialu YIN, Wuhan (CN); Xiang FU, Wuhan (CN); Zhichao DU, Wuhan (CN); Yu WANG, Wuhan (CN); Shouchun PENG, Wuhan (CN)

(21) Appl. No.: 19/222,959

(22) Filed: May 29, 2025

(30) Foreign Application Priority Data
Dec. 13, 2024 (CN) 202411846561.3

(51) Int. Cl. H10B 80/00; G11C 11/4091; H01L 23/00; H01L 25/00; H01L 25/065; H01L 25/18; H10B 12/00

(52) U.S. Cl. CPC H10B 80/00; G11C 11/4091; H10B 12/315; H10B 12/50; H10W 90/00; H10W 80/312; H10W 80/327; H10W 90/792

(57) ABSTRACT

The present disclosure provides a memory device and formation method thereof as well as a memory system. In an implementation, the memory device includes a first semiconductor structure and a second semiconductor structure. The first semiconductor structure includes a memory array, a plurality of bit lines, a first conductive connection layer, and a second conductive connection layer. The second semiconductor structure includes a plurality of sense amplifiers. One sense amplifier of the plurality of sense amplifiers is coupled with two bit lines of the plurality of bit lines, and a main conductive line in a coupling path between one of the two bit lines coupled with the one sense amplifier and the one sense amplifier is located in the first conductive connection layer.

### CROSS-REFERENCE TO RELATED APPLICATIONS

This application claims priority to Chinese Patent Application No. 202411846561.3, filed on Dec. 13, 2024, which is hereby incorporated by reference in its entirety.

### TECHNICAL FIELD

The present disclosure relates to the field of semiconductor technology, and in particular, to a memory device and forming method thereof as well as a memory system.

### BACKGROUND

With the continuous development of science and technology, semiconductor devices are widely used in various electronic devices and electronic products. For example, a dynamic random access memory (DRAM), as a volatile memory, is a semiconductor memory device commonly used in computers.

### SUMMARY

Examples of the present disclosure provide a memory device and a forming method thereof, as well as a memory system.

In a first aspect, an example of the present disclosure provides a memory device including a first semiconductor structure and a second semiconductor structure stacked along a first direction, wherein
the first semiconductor structure includes a memory array, a plurality of bit lines coupled with the memory array, a first conductive connection layer, and a second conductive connection layer; wherein the second conductive connection layer is located between the first conductive connection layer and the second semiconductor structure in the first direction; and
the second semiconductor structure includes a plurality of sense amplifiers; one sense amplifier of the plurality of sense amplifiers is coupled with two bit lines of the plurality of bit lines, and a main conductive line in a coupling path between one of the two bit lines coupled with the one sense amplifier and the one sense amplifier is located in the first conductive connection layer, and a main conductive line in a coupling path between the other of the two bit lines coupled with the one sense amplifier and the one sense amplifier is located in the second conductive connection layer; and an extension dimension of a main conductive line in the coupling path in a direction perpendicular to the first direction is larger than extension dimensions of other conductive lines in the coupling path in the direction perpendicular to the first direction.

In an example implementation, the plurality of bit lines are located between the memory array and the first conductive connection layer in the first direction; the plurality of bit lines extend along a second direction and are arranged along the second direction and a third direction; and wherein the second direction is perpendicular to the third direction, and both the second direction and the third direction are perpendicular to the first direction; and
the memory array includes a first memory block; the plurality of bit lines include a plurality of first bit lines coupled with the first memory block; a main conductive line in a coupling path between one of two first bit lines adjacent in the third direction among the plurality of first bit lines and a sense amplifier is located in the first conductive connection layer, and a main conductive line in a coupling path between the other of the two first bit lines adjacent in the third direction and a sense amplifier is located in the second conductive connection layer.

In an example implementation, the main conductive line in the first conductive connection layer and the main conductive line in the second conductive connection layer which are coupled with the one sense amplifier are arranged along the first direction.

In an example implementation, the plurality of bit lines further include a plurality of second bit lines coupled with the first memory block; and the plurality of second bit lines and the plurality of first bit lines are alternately arranged in the third direction; and
a main conductive line in a coupling path between one of two second bit lines adjacent in the third direction among the plurality of second bit lines and a sense amplifier is located in the first conductive connection layer, and a main conductive line in a coupling path between the other of the two second bit lines adjacent in the third direction and a sense amplifier is located in the second conductive connection layer.

In an example implementation, the memory array further includes:
a second memory block and a third memory block; wherein the first memory block is located between the second memory block and the third memory block in the second direction; the plurality of bit lines further include a plurality of third bit lines coupled with the second memory block and a plurality of fourth bit lines coupled with the third memory block; one first bit line of the plurality of first bit lines and one third bit line of the plurality of third bit lines are coupled with the same sense amplifier; and one second bit line of the plurality of second bit lines and one fourth bit line of the plurality of fourth bit lines are coupled with the same sense amplifier.

In an example implementation, a sense amplifier coupled with the first bit line is stacked with the first memory block in the first direction, and a sense amplifier coupled with the second bit line is stacked with the third memory block in the first direction.

In an example implementation, the first semiconductor structure further includes:
a first conductive structure extending along the first direction, wherein one of two opposite ends of the first conductive structure along the first direction is connected with the bit line, and the other of the two opposite ends of the first conductive structure along the first direction is coupled with the main conductive line in the first conductive connection layer; and
a second conductive structure extending along the first direction, wherein one of two opposite ends of the second conductive structure along the first direction is connected with the bit line, and the other of the two opposite ends of the second conductive structure along the first direction is coupled with the main conductive line in the second conductive connection layer.

In an example implementation, the first semiconductor structure further includes:
a third conductive connection layer located between the first conductive connection layer and the second conductive connection layer; a coupling path between one of the two bit lines coupled with the one sense amplifier and the one sense amplifier further includes a conductive line in the third conductive connection layer, and a coupling path between the other of the two bit lines coupled with the one sense amplifier and the one sense amplifier further includes a conductive line in the third conductive connection layer.

In an example implementation, the memory device further includes:
a bonding layer located between the first semiconductor structure and the second semiconductor structure; wherein the bonding layer includes a bonding structure; the bonding structure is coupled with a main conductive line in the first conductive connection layer, or the bonding structure is coupled with a main conductive line in the second conductive connection layer, and a coupling path between the bit line and the sense amplifier includes the bonding structure.

In an example implementation, the second semiconductor structure further includes:
a fourth conductive connection layer located between the plurality of sense amplifiers and the bonding layer; wherein the bonding structure is coupled with a conductive line in the fourth conductive connection layer, and the conductive line in the fourth conductive connection layer is coupled with the sense amplifier; and a coupling path between the bit line and the sense amplifier includes the conductive line in the fourth conductive connection layer.

In an example implementation, the memory array includes:
memory cells arranged in an array along the second direction and the third direction, wherein the memory cell includes a transistor structure and a capacitor structure coupled with the transistor structure.

In a second aspect, an example of the present disclosure provides a memory system, including:
at least one memory device; and
a controller coupled with the at least one memory device and configured to control the at least one memory device, wherein
the memory device includes a first semiconductor structure and a second semiconductor structure stacked along a first direction, wherein
   the first semiconductor structure includes a memory array, a plurality of bit lines coupled with the memory array, a first conductive connection layer, and a second conductive connection layer; wherein the second conductive connection layer is located between the first conductive connection layer and the second semiconductor structure in the first direction; and
   the second semiconductor structure includes a plurality of sense amplifiers; one sense amplifier of the plurality of sense amplifiers is coupled with two bit lines of the plurality of bit lines, and a main conductive line in a coupling path between one of the two bit lines coupled with the one sense amplifier and the one sense amplifier is located in the first conductive connection layer, and a main conductive line in a coupling path between the other of the two bit lines coupled with the one sense amplifier and the one sense amplifier is located in the second conductive connection layer; and an extension dimension of a main conductive line in the coupling path in a direction perpendicular to the first direction is larger than extension dimensions of other conductive lines in the coupling path in the direction perpendicular to the first direction.

In a third aspect, an example of the present disclosure provides a forming method of a memory device including:
forming a first semiconductor structure, including: forming a memory array, a plurality of bit lines coupled with the memory array, a first conductive connection layer and a second conductive connection layer;
forming a second semiconductor structure, including: forming a plurality of sense amplifiers; and
stacking the first semiconductor structure and the second semiconductor structure along a first direction; wherein the second conductive connection layer is located between the first conductive connection layer and the second semiconductor structure in the first direction; one sense amplifier of the plurality of sense amplifiers is coupled with two bit lines of the plurality of bit lines, and a main conductive line in a coupling path between one of the two bit lines coupled with the one sense amplifier and the one sense amplifier is located in the first conductive connection layer, and a main conductive line in a coupling path between the other of the two bit lines coupled with the one sense amplifier and the one sense amplifier is located in the second conductive connection layer; and an extension dimension of a main conductive line in the coupling path in a direction perpendicular to the first direction is larger than extension dimensions of other conductive lines in the coupling path in the direction perpendicular to the first direction.

In an example implementation, the plurality of bit lines are located between the memory array and the first conductive connection layer in the first direction; the plurality of bit lines extend along a second direction and are arranged along the second direction and a third direction; and wherein the second direction is perpendicular to the third direction, and both the second direction and the third direction are perpendicular to the first direction; wherein:
forming the memory array includes: forming a first memory block; and
forming the plurality of bit lines includes: forming a plurality of first bit lines coupled with the first memory block; a main conductive line in a coupling path between one of two first bit lines adjacent in the third direction among the plurality of first bit lines and a sense amplifier is located in the first conductive connection layer, and a main conductive line in a coupling path between the other of the two first bit lines adjacent in the third direction and a sense amplifier is located in the second conductive connection layer.

In an example implementation, forming the plurality of bit lines further includes:
forming a plurality of second bit lines coupled with the first memory block; wherein the plurality of second bit lines and the plurality of first bit lines are alternately arranged in the third direction; and a main conductive line in a coupling path between one of two second bit lines adjacent in the third direction among the plurality of second bit lines and a sense amplifier is located in the first conductive connection layer, and a main conductive line in a coupling path between the other of the two second bit lines adjacent in the third direction and a sense amplifier is located in the second conductive connection layer.

In an example implementation, forming the memory array further includes:
forming a second memory block and a third memory block; wherein the first memory block is located between the second memory block and the third memory block in the second direction; the plurality of bit lines further include a plurality of third bit lines coupled with the second memory block and a plurality of fourth bit lines coupled with the third memory block; one first bit line of the plurality of first bit lines and one third bit line of the plurality of third bit lines are coupled with the same sense amplifier; and one second bit line of the plurality of second bit lines and one fourth bit line of the plurality of fourth bit lines are coupled with the same sense amplifier.

In an example implementation, forming the first semiconductor structure further includes:
forming a first conductive structure extending along the first direction and a second conductive structure extending along the first direction before forming the first conductive connection layer and the second conductive connection layer, wherein one of two opposite ends of the first conductive structure along the first direction is connected with the bit line, and one of the two opposite ends of the second conductive structure along the first direction is connected with the bit line; wherein
after the first conductive connection layer and the second conductive connection layer are formed, the other of the two opposite ends of the first conductive structure along the first direction is coupled with the main conductive line in the first conductive connection layer, and the other of the two opposite ends of the second conductive structure along the first direction is coupled with the main conductive line in the second conductive connection layer.

In an example implementation, forming the first semiconductor structure further includes:
forming a third conductive connection layer; wherein the third conductive connection layer is located between the first conductive connection layer and the second conductive connection layer; a coupling path between one of the two bit lines coupled with the one sense amplifier and the one sense amplifier further includes a conductive line in the third conductive connection layer, and a coupling path between the other of the two bit lines coupled with the one sense amplifier and the one sense amplifier further includes a conductive line in the third conductive connection layer.

In an example implementation, the forming method of the memory device further includes:
forming a bonding layer between the first semiconductor structure and the second semiconductor structure; wherein the bonding layer includes a bonding structure; the bonding structure is coupled with a main conductive line in the first conductive connection layer, or the bonding structure is coupled with a main conductive line in the second conductive connection layer, and a coupling path between the bit line and the sense amplifier includes the bonding structure.

In an example implementation, forming the second semiconductor structure further includes:
forming a fourth conductive connection layer; wherein the fourth conductive layer is located on one side of the plurality of sense amplifiers in the first direction; a conductive line in the fourth conductive layer is coupled with a sense amplifier, and the bonding structure is coupled with the conductive line in the fourth conductive connection layer; and a coupling path between the bit line and the sense amplifier includes the conductive line in the fourth conductive connection layer.

In an example implementation, forming the memory array includes:
forming memory cells arranged in an array along the second direction and the third direction, wherein the memory cell includes a transistor structure and a capacitor structure coupled with the transistor structure.

In the technical solutions provided by the present disclosure, in the memory device, the main conductive line in the coupling path between one of two bit lines coupled with a sense amplifier and the sense amplifier is located in the first conductive connection layer, and the main conductive line in the coupling path between the other of the two bit lines coupled with the sense amplifier and the sense amplifier is located in the second conductive connection layer, and the parasitic capacitance between the main conductive lines in the first conductive connection layer or the parasitic capacitance between the main conductive lines in the second conductive connection layer can be configured to compensate the parasitic capacitance between adjacent bit lines, thereby the degree of sensing margin decrease caused by the parasitic capacitance between adjacent bit lines can be decreased and the reliability of the memory device can be improved.

### BRIEF DESCRIPTION OF THE DRAWINGS

FIG. 1 is a schematic diagram of an electronic device provided by an example of the present disclosure;

FIG. 2 is a schematic diagram of a DRAM provided by an example of the present disclosure;

FIG. 3a is a schematic circuit diagram of a sense amplifier provided by an example of the present disclosure;

FIG. 3b is a first schematic diagram of the voltages on bit lines in a read operation provided by an example of the present disclosure;

FIG. 4 is a schematic diagram of a memory device provided by an example of the present disclosure;

FIG. 5 is a schematic diagram of a memory bank in a memory array provided by an example of the present disclosure;

FIG. 6 is a schematic diagram of a peripheral circuit stacked with a memory block provided by an example of the present disclosure;

FIG. 7 is a schematic cross-sectional view of a memory device provided by an example of the present disclosure;

FIG. 8 is a schematic diagram of the arrangement of a plurality of bit lines coupled with a memory array provided by an example of the present disclosure;

FIG. 9 is a second schematic diagram of the voltages on bit lines in a read operation provided by an example of the present disclosure;

FIG. 10 is a schematic diagram of the arrangement of various structures in a memory device in the first direction provided by an example of the present disclosure;

FIG. 11 is a schematic diagram of connections of bit lines, main conductive lines and sense amplifiers in a memory device provided by an example of the present disclosure;

FIG. 12 is a first schematic diagram of the arrangement of main conductive lines coupled with first bit lines and third bit lines provided by a specific example of the present disclosure;

FIG. 13 is a schematic cross-sectional view along line AA′ of FIG. 12;

FIG. 14 is a schematic diagram of the arrangement of main conductive lines coupled with second bit lines and fourth bit lines provided by a specific example of the present disclosure;

FIG. 15 is a schematic cross-sectional view along line BB′ of FIG. 14;

FIG. 16 is a third schematic diagram of the voltages on bit lines in a read operation provided by an example of the present disclosure;

FIG. 17 is a second schematic diagram of the arrangement of main conductive lines coupled with first bit lines and third bit lines provided by a specific example of the present disclosure; and

FIG. 18 is a schematic flowchart of a forming method of a memory device provided by an example of the present disclosure.

### DETAILED DESCRIPTION

Examples of the present disclosure will be described in more detail below with reference to the accompanying drawings. Although the examples of the present disclosure are shown in the drawings, it should be understood that the present disclosure may be implemented in various forms and should not be limited by the specific examples set forth herein. On the contrary, these examples are provided to enable a more thorough understanding of the present disclosure and to fully convey the scope of the present disclosure to those skilled in the art.

In the following description, numerous specific details are presented in order to provide a more thorough understanding of the present disclosure. However, it will be apparent to those skilled in the art that the present disclosure may be practiced without one or more of these details. In other examples, in order to avoid confusion with the present disclosure, some technical features well-known in the art are not described; that is, not all features of actual examples are described herein, and well-known functions and structures are not described in detail.

In the drawings, like numbers refer to like elements throughout.

It should be understood that spatial relationship terms such as “under”, “below”, “lower”, “beneath”, “over”, “upper” and the like may be used herein for convenience of description to describe the relationship between one element or feature and other elements or features shown in the drawings. It will be understood that the spatially relative terms aims to encompass different orientations of the device in use and operation in addition to the orientation depicted in the figures. For example, if a device in the figures is turned over, an element or feature described as “below” or “beneath” or “under” other elements or features would then be oriented “above” the other elements or features. Thus, the example terms “below” and “under” can encompass both up and down orientations. The device may be otherwise oriented (rotated 90 degrees or at other orientations) and the spatial descriptive terms used herein are interpreted accordingly.

The terms are used herein to describe particular examples only and are not intended to limit the disclosure. As used herein, the singular forms “a”, “an” and “the” are intended to include the plural forms as well, unless the context clearly indicates otherwise. It should be further understood that the terms “consist of” and/or “include”, when used in this specification, specify the presence of the stated features, integers, steps, operations, elements, and/or components, but do not preclude the presence or addition of one or more other features, integers, steps, operations, elements, components, and/or groups. As used herein, the term “and/or” includes any and all combinations of the associated listed items.

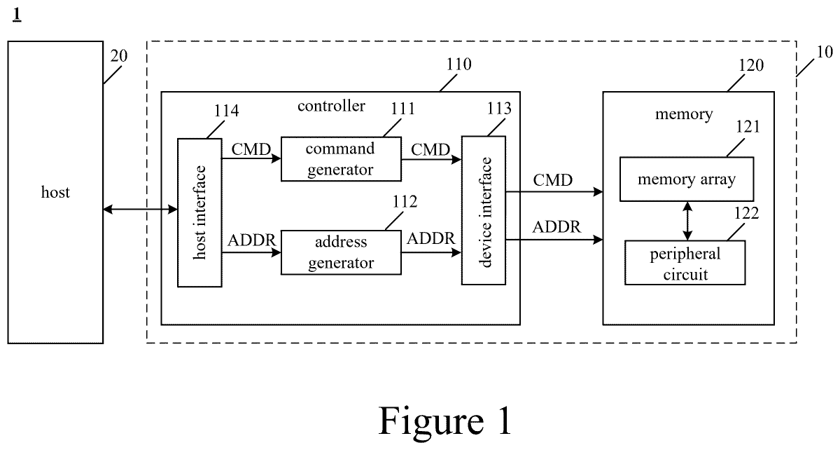

FIG. 1 is a schematic diagram of an electronic device according to an example of the present disclosure. The electronic device 1 may be a mobile phone, a desktop computer, a laptop computer, a tablet computer, a vehicle computer, a gaming console, a printer, a positioning device, a wearable electronic device, a smart sensor, a virtual reality (VR) device, an augmented reality (AR) device, or any other suitable electronic device having a memory therein.

As shown in FIG. 1, the electronic device 1 may include a memory system 10 and a host 20, and the memory system 10 may include a controller 110 and a memory 120. The host 20 may include a processor of the electronic device 1, such as a central processing unit (CPU) or a system on chip (SoC) (e.g., an application processor (AP)). The controller 110 is coupled with both the host 20 and the memory 120, and the controller 110 may be configured to communicate with the host 20 and control the memory 120.

In some examples, the controller 110 may be configured to control the operations of the memory 120, such as read operations, erase operations, write operations, refresh operations, etc. In some implementations, the controller 110 is further configured to process an error correction code (ECC) of the data read from the memory 120 or written to the memory 120. In some other implementations, the controller 110 may also be configured to perform any other suitable operations, such as formatting the memory 120.

In some examples, the controller 110 may receive data, commands, and addresses from the host 20 and may send data, commands, and addresses to the memory 120. In particular, the controller 110 may include a command generator 111, an address generator 112, a device interface 113, and a host interface 114. The controller 110 may receive data, commands and addresses from the host 20 through the host interface 114, decode, through the command generator 111, commands received from the host 20 to generate access commands (CMD), and provide the access CMD to the memory 120 through the device interface 113. The controller 110 may decode, through the address generator 112, the address received from the host interface 114 to generate an address (ADDR) to be accessed in the memory array 121, and may provide the ADDR to be accessed to the memory 120 through the device interface 113. The access command may be a signal indicating the memory 120 to write or read data by accessing one or more memory cells in the memory array 121 corresponding to the ADDR. In addition, the controller 110 may also send a refresh command to the memory 120, and the refresh command may be a signal indicating the memory 120 to read and re-write data by accessing one or more memory cells of the memory array 121 corresponding to the ADDR.

In some specific examples, the memory 120 may be a random access memory (RAM), such as a dynamic random access memory (DRAM), a synchronous dynamic random access memory (SDRAM), a static random access memory (SRAM), a double data rate SDRAM (DDR SDRAM), a phase-change random access memory (PRAM), a resistive random access memory (ReRAM), a magnetic random access memory (MRAM), etc. Next, the memory 120 of DRAM will be used as an example for description.

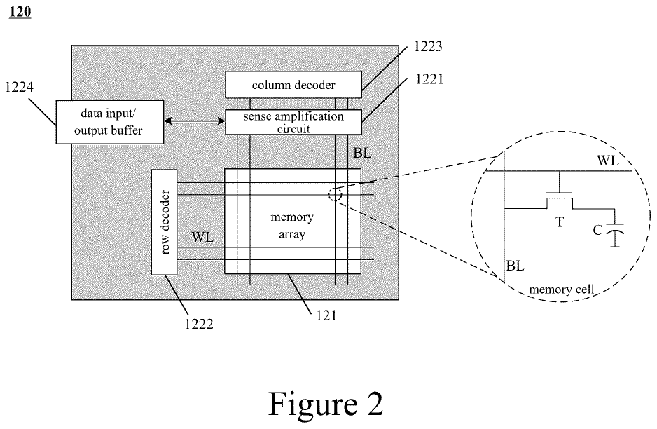

In some examples, FIG. 2 is a schematic diagram of a DRAM according to an example of the present disclosure. Referring to FIG. 1 and FIG. 2 in combination, the DRAM includes a memory array 121 and a peripheral circuit 122 coupled with the memory array 121, the peripheral circuit 122 may include a sense amplification circuit 1221, a row decoder 1222, a column decoder 1223, a data input/output buffer 1224, and the like, and the memory array 121 includes a plurality of memory cells arranged in an array, a plurality of memory cells located in the same row are coupled with a word line (WL), and a plurality of memory cells located in the same column are coupled with a bit line (BL). Each memory cell includes one transistor (T) and one capacitor (C), a WL is connected with a gate of the transistor T, a BL is connected with one of a source and a drain of the transistor T, the other one of the source and the drain of the transistor T is connected with one electrode of the capacitor C, and the other electrode of the capacitor C is connected with a fixed voltage. The memory cells are configured to store “1” or “0” utilizing the amount of charge stored by the capacitance C. By specifying the row address and the column address, each memory cell in the DRAM chip may be independently accessed, and a read operation, a write operation, or a refresh operation may be performed on the data stored therein.

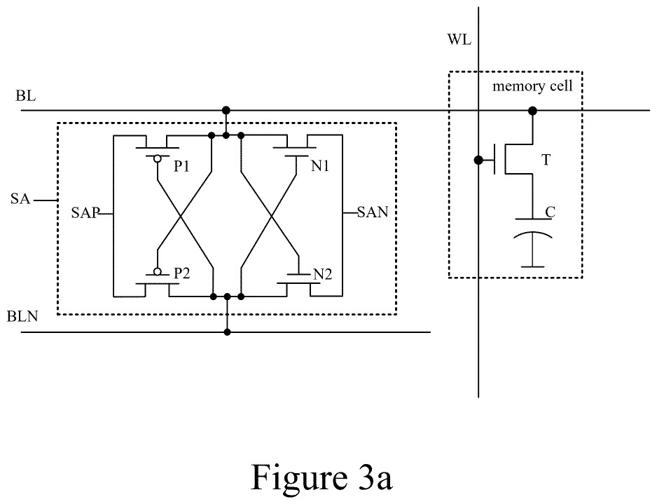

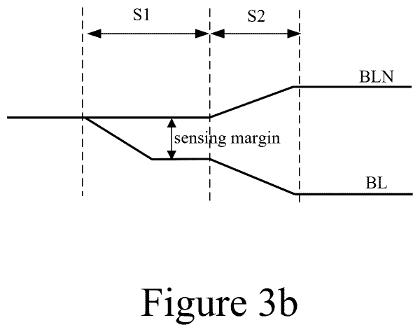

In some examples, the sense amplification circuit 1221 may include a plurality of sense amplifiers, each sense amplifier is coupled with two bit lines. FIG. 3a is a schematic circuit diagram of the sensing amplifier provided by an example of the present disclosure. As shown in FIG. 3a, the BL and the complementary bit line (BLN) thereof are coupled to a sense amplifier (SA), and the SA may include four transistors, wherein the transistor P1 and the transistor P2 are both PMOS transistors, and the transistor N1 and the transistor N2 are both NMOS transistors. The gate of the transistor P1 is coupled with the complementary bit line BLN, the drain of the transistor P1 is coupled with the bit line BL, and the source of the transistor P1 is coupled with a P-type sense-amplifier P-Fet Control (SAP); the gate of the transistor P2 is coupled with the bit line BL, the drain of the transistor P2 is coupled with the complementary bit line BLN, and the source of the transistor P2 is coupled with the SAP; the gate of the transistor N1 is coupled with the complementary bit line BLN, the drain of the transistor N1 is coupled with the bit line BL, and the source of the transistor N1 is coupled with an N-type sense-amplifier N-Fet Control (SAN); and the gate of the transistor N2 is coupled with the bit line BL, the drain of the transistor N2 is coupled with the complementary bit line BLN, and the source of the transistor N2 is coupled with the SAN.

It should be noted that the circuit structure of the sense amplifier SA shown in FIG. 3a is merely an example, and is not to be specific limit for the sense amplifier in the memory device provided by the present disclosure.

FIG. 3b is a first schematic diagram of the voltages on bit lines in a read operation provided by an example of the present disclosure, here, taking the bit line BL being coupled with the selected memory cell in the read operation, and the data stored in the selected memory cell being “0” as an example. Referring to FIG. 3a and FIG. 3b in combination, before the charge sharing phase S1, the transistor T of the memory cell is in an off state, and the bit line BL and the complementary bit line BLN thereof can be pre-charged to the same voltage; then, in the charge sharing phase S1, the transistor T of the memory cell is turned on, and a charge stored in the capacitor C of the memory cell can be transferred to the bit line BL, so that the voltage on the bit line BL decreases, and thus, after the voltage on the bit line BL remains stable, a voltage difference can be generated between the bit line BL and the complementary bit line BLN, and the voltage difference is the sensing margin. In the sensing phase S2 after the charge sharing phase S1, the SAN received by the sense amplifier SA is a low level signal, the SAP is a high level signal, the transistor P2 and the transistor N1 are turned on, so that the voltage on the bit line BL further decreases and the voltage on the complementary bit line BLN increases, thus the sense amplifier SA can further amplify the voltage difference between the bit line BL and the complementary bit line BLN, so that the data “0” stored in the memory cell can be read out.

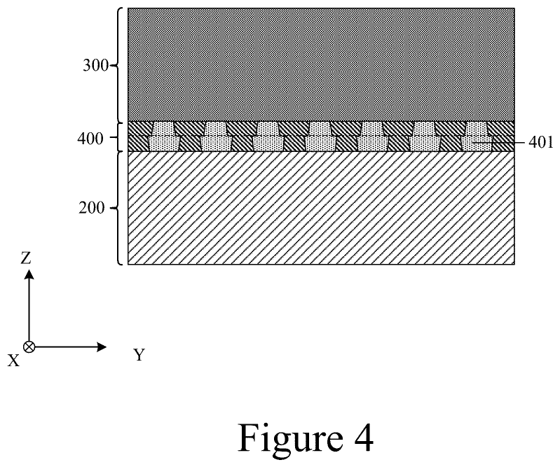

FIG. 4 is a schematic diagram of a memory device provided by an example of the present disclosure, as shown in FIG. 4, the memory device includes a first semiconductor structure 200, a second semiconductor structure 300, and a bonding layer 400 located between the first semiconductor structure 200 and the second semiconductor structure 300 that are stacked along the Z direction, the memory array 121 in the above example may be located in the first semiconductor structure 200, the peripheral circuit 122 may be located in the second semiconductor structure 300, and the memory array 121 and the peripheral circuit 122 may be coupled through the bonding structures 401 in the bonding layer 400, so that a memory device with a three-dimensional architecture may be formed, which is beneficial for realizing high-density integration of DRAM. Here, the bonding layer 400 may be a hybrid bonding layer formed by a hybrid bonding process, including a dielectric layer and the bonding structures 401 penetrating the dielectric layer along the Z direction.

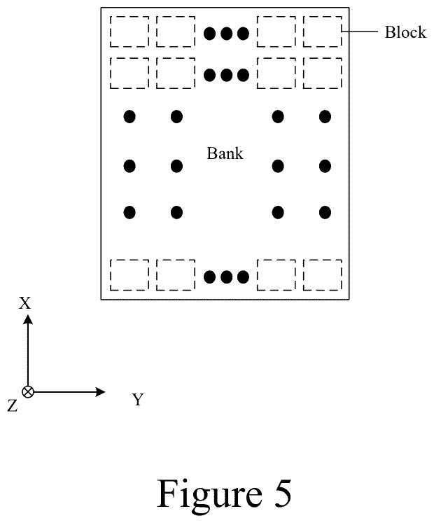

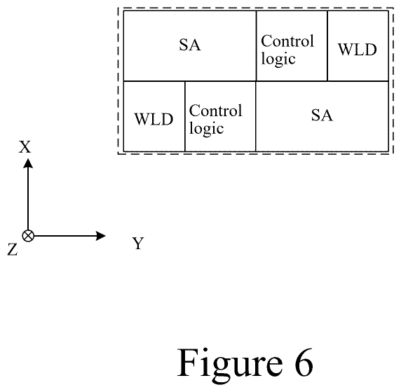

FIG. 5 is a schematic diagram of memory banks in a memory array provided by an example of the present disclosure, the memory array 121 includes at least one memory bank, and the memory bank includes a plurality of memory blocks arranged in an array. FIG. 6 is a schematic diagram of a peripheral circuit stacked with one memory block provided by a specific example, and the peripheral circuit stacked with one memory block in the Z direction may include a sense amplifier (SA), a word line driver (WLD), and a control logic circuit which are coupled with the memory block.

In the example of the present disclosure, a part of the peripheral circuits coupled with the memory blocks may be stacked with the memory blocks in the Z direction, so that the area of the memory device may be further reduced, and in addition, the length of the conductive connection path between the memory array and the peripheral circuits may also be shortened.

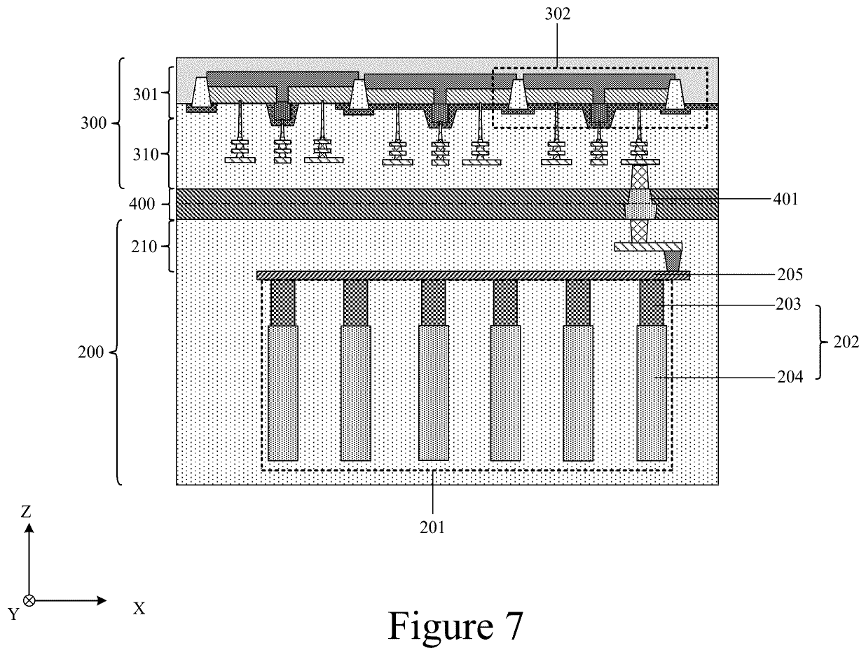

In some specific examples, FIG. 7 is a schematic cross-sectional view of a memory device provided by an example of the present disclosure, and the memory device includes a first semiconductor structure 200 and a second semiconductor structure 300 stacked along a first direction. In particular, the first semiconductor structure 200 includes a memory array 201, the second semiconductor structure 300 includes a peripheral circuit 301, the memory array 201 includes a plurality of memory cells 202 arranged in an array along the second direction and the third direction, the memory cell 202 include a transistor structure 203 and a capacitor structure 204 coupled with the transistor structure 203, the plurality of memory cells 202 arranged along the second direction are coupled with a bit line 205 extending along the second direction, the bit line 205 may be coupled with a bonding structure 401 in the bonding layer 400 through an interconnection structure in the first interconnection layer 210, and the bonding structure 401 may be coupled with a sense amplifier 302 in the peripheral circuit 301 through an interconnection structure in the second interconnection layer 310.

In an example of the present disclosure, the interconnection structure in the first interconnection layer 210, the bonding structure 401 in the bonding layer 400, and the interconnection structure in the second interconnection layer 310 may constitute a coupling path between the bit line 205 in the first semiconductor structure 200 and the sense amplifier 302 in the second semiconductor structure 300. Here, the interconnection structure may include a plurality of conductive lines extending along a direction perpendicular to the first direction and a plurality of conductive structures connecting two conductive lines adjacent in the first direction, and the numbers of the conductive lines and the conductive structures shown in FIG. 7 are merely illustrative and are not intended to limit the present disclosure.

In an example of the present disclosure, the second direction is perpendicular to the third direction, and both the second direction and the third direction are perpendicular to the first direction, here, taking the first direction as the Z direction, the second direction as the X direction, and the third direction as the Y direction as an example.

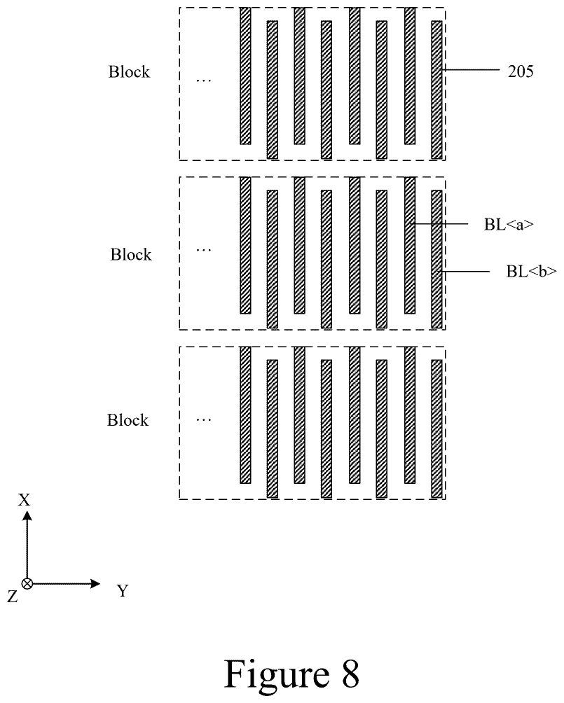

In some examples, FIG. 8 is a schematic diagram of the arrangement of a plurality of bit lines coupled with a memory array provided by an example of the present disclosure; and referring to FIG. 7 and FIG. 8 in combination, the plurality of bit lines 205 are all located between the memory array 201 and the second semiconductor structure 300 and are located substantially at the same height in the first direction; the plurality of bit lines 205 extend along the second direction and are arranged along the second direction and the third direction; and the bit lines 205 coupled with one memory block are arranged along the third direction. The bit line 205 includes a conductive material, and a dielectric material is filled between the bit lines 205, a parasitic capacitance can be generated between adjacent bit lines 205, and with the improvement of memory device integration, the spacing between adjacent bit lines 205 is shortened, and the coupling effect between adjacent bit lines 205 becomes more severe.

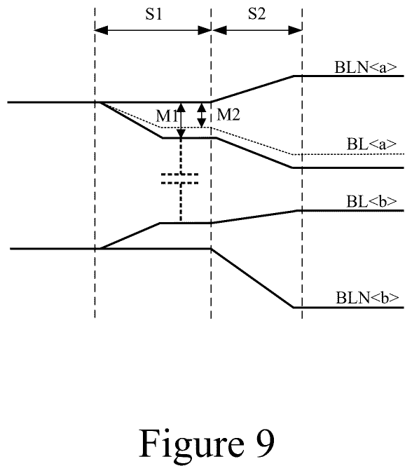

FIG. 9 is a second schematic diagram of the voltages on the bit lines in a read operation provided by an example of the present disclosure. Referring to FIG. 8 and FIG. 9 in combination, taking two adjacent bit lines BL<a> and BL<b> coupled with a memory block as an example, when the voltage applied to the selected word line causes the transistors in a plurality of selected memory cells arranged along the third direction to be turned on, if the data stored in the selected memory cell coupled with BL<a> is “0” and the data stored in the selected memory cell coupled with BL<b> is “1”, then in the charge sharing stage S1, the voltage on BL<a> decreases while the voltage on BL<b> increases. As the coupling effect induced by the parasitic capacitance between BL<a> and BL<b> may cause the degree of voltage drop on BL<a> to decrease, thereby causing the sensing margin between BL<a> and its complementary bit line BLN<a> to decrease. For example, in the case where both the selected memory cell coupled with BL<a> and the selected memory cell coupled with BL<b> store “0”, the sensing margin between BL<a> and its complementary bit line BLN<a> is M1, while in the case where the data stored in the selected memory cell coupled with BL<a> is “0” and the data stored in the selected memory cell coupled with BL<b> is “1”, the sensing margin between BL<a> and its complementary bit line BLN<a> decreases to M2, and the decrease in the sensing margin may cause the sensing amplifier coupled with BL<a> and BLN<a> to fail to correctly amplify the voltage difference between BL<a> and BLN<a>, ultimately leading to read errors and reduced reliability of the memory device.

In some specific examples, in order to improve the efficiency of a read operation, the read operation may be performed on a plurality of memory cells coupled with one word line at the same time, in this case, when only data stored in one of the plurality of memory cells is different from data stored in the other memory cells, the above problem of decreased sensing margin caused by the parasitic capacitance between bit lines will be more severe. For example, when the data to be read is “. . . 1110111 . . . ”, in the charge sharing stage, the voltage on the bit line coupled with the memory cell storing “0” needs to decrease, but the voltages on a plurality of bit lines adjacent to the bit line can all increase, and the coupling effect between the bit lines can cause the decrease trend of the voltage on the bit line to be suppressed to a larger extent, thereby causing the sensing margin to be severely compressed, and finally causing that “0” cannot be read out. Similarly, when the data to be read is “. . . 0001000 . . . ”, in the charge sharing stage, the voltage on the bit line coupled with the memory cell storing “1” needs to increase, but the voltages on a plurality of bit lines adjacent to the bit line can all decrease, and the coupling effect between the bit lines can cause the increase trend of the voltage on the bit line to be suppressed to a larger extent, thereby causing the sensing margin to be severely compressed, and finally causing that “1” cannot be read out.

Therefore, in order to improve the reliability of the read operation of the memory device, the negative impact of the parasitic capacitance between the bit lines on the sensing margin needs to be reduced as much as possible. To this end, the present disclosure proposes the following examples.

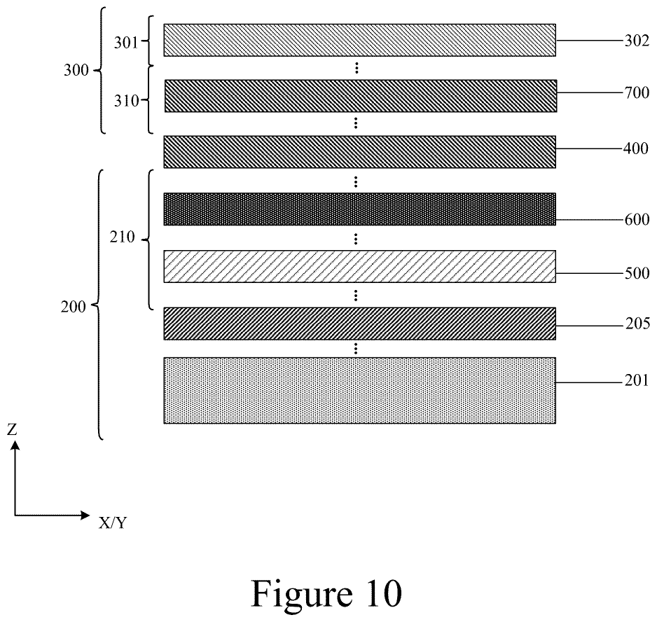

The present disclosure provides a memory device. FIG. 10 is a schematic diagram of arrangement of the various structures in a first direction in the memory device provided by an example of the present disclosure. Referring to FIG. 7 and FIG. 10 in combination, the memory device includes a first semiconductor structure 200 and a second semiconductor structure 300 stacked along the first direction, the first semiconductor structure 200 includes a memory array 201, a plurality of bit lines 205 coupled with the memory array 201, a first conductive connection layer 500, and a second conductive connection layer 600; the second conductive connection layer 600 is located between the first conductive connection layer 500 and the second semiconductor structure 300 in the first direction; and the second semiconductor structure 300 includes a plurality of sense amplifiers 302. Here, the first conductive connection layer 500 and the second conductive connection layer 600 are both located in the first interconnection layer 210 of the first semiconductor structure 200, and in addition, the first interconnection layer 210 may further include other conductive connection layers.

It should be noted that FIG. 10 only shows the relative positional relationship of various structures in the memory device in the first direction, and is not intended to limit the shape or size of various structures in the memory device.

In some examples, referring to FIG. 7 and FIG. 10 in combination, the memory device further includes: a bonding layer 400 located between the first semiconductor structure 200 and the second semiconductor structure 300; the bonding layer 400 includes a bonding structure 401; the bonding structure 401 is coupled with a main conductive line in the first conductive connection layer 500, or the bonding structure 401 is coupled with a main conductive line in the second conductive connection layer 600; and a coupling path between a bit line 205 and a sense amplifier 302 includes the bonding structure 401.

In some examples, the second semiconductor structure 300 further includes: a fourth conductive connection layer 700 located between the plurality of sense amplifiers 302 and the bonding layer 400; the bonding structure 401 is coupled with a conductive line in the fourth conductive connection layer 700, and the conductive line in the fourth conductive connection layer 700 is coupled with the sense amplifier 302; and the coupling path between the bit line 205 and the sense amplifier 302 includes the conductive line in the fourth conductive connection layer 700. Here, the fourth conductive connection layer 700 may be at least one conductive connection layer in the second interconnection layer 310.

In some examples, the main conductive line in the coupling path between one of the two bit lines 205 coupled with one sense amplifier 302 and the sense amplifier 302 is located in the first conductive connection layer 500, and the main conductive line in the coupling path between the other of the two bit lines 205 coupled with one sense amplifier 302 and the sense amplifier 302 is located in the second conductive connection layer 600. Here, the extension dimension of the main conductive line in the coupling path between the bit line 205 and the sense amplifier 302 in a direction perpendicular to the first direction is larger than the extension dimensions of other conductive lines in the coupling path in the direction perpendicular to the first direction.

It should be noted that, in the examples of the present disclosure, the conductive lines located in the same conductive connection layer are located substantially at the same height in the first direction, and the coupling path between the bit line 205 and the sense amplifier 302 may include a plurality of conductive lines located in different conductive connection layers. The dimensions of the conductive line include a length, a width and a thickness of the conductive line; a thickness direction of the conductive line is the first direction; a length direction of the conductive line, that is, the extension direction of the conductive line, may be any direction perpendicular to the first direction, and the extension directions of different conductive lines may be different, but are all perpendicular to the first direction; and the width direction of the conductive line is perpendicular to the length direction thereof, and the width of the conductive line is less than the length thereof. The dimension of the conductive line in the extension direction is the extension dimension of the conductive line in the direction perpendicular to the first direction, that is, the length of the conductive line. The main conductive line in the coupling path is a conductive line having a largest extending dimension in the direction perpendicular to the first direction among the plurality of conductive lines in the coupling path, that is, a conductive line having a largest length.

The connection relationship between the bit lines, the main conductive lines and the sense amplifiers in the memory device provided by an example of the present disclosure will be described below with reference to specific examples.

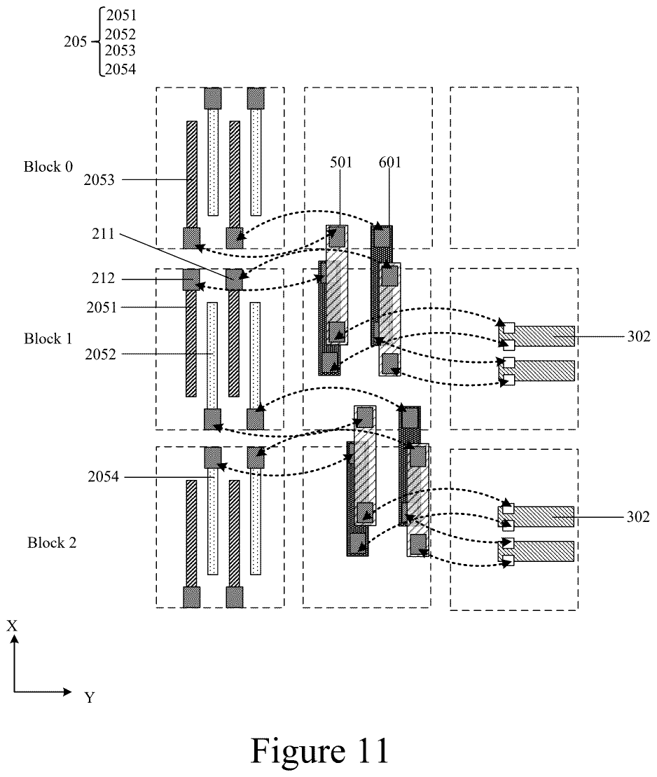

FIG. 11 is a schematic diagram of connection of bit lines, main conductive lines and sense amplifiers in a memory device provided by an example of the present disclosure. The memory array includes a first memory block Block1, a second memory block Block0 and a third memory block Block2, wherein the first memory block Block1 is located between the second memory block Block0 and the third memory block Block2 in the second direction. The coupling path between the bit line 205 and the sense amplifier 302 includes the main conductive line 501 in the first conductive connection layer or the main conductive line 601 in the second conductive connection layer. Here, for ease of observation, the main conductive line 501 in the first conductive connection layer has a perspective effect.

In some examples, the first semiconductor structure 200 further includes: a first conductive structure 211 extending along the first direction, wherein one of two opposite ends of the first conductive structure 211 along the first direction is connected with a bit line 205, and the other of the two opposite ends of the first conductive structure 211 along the first direction is coupled with the main conductive line 501 in the first conductive connection layer; and a second conductive structure 212 extending along the first direction, wherein one of two opposite ends of the second conductive structure 212 along the first direction is connected with a bit line 205, and the other of the two opposite ends of the second conductive structure 212 along the first direction is coupled with the main conductive line 601 in the second conductive connection layer. Here, the first conductive structure 211 or the second conductive structure 212 may be connected with one of two opposite ends of the bit line 205 in the second direction, and the bit line 205 may be coupled with the main conductive line 501 in the first conductive connection layer through the first conductive structure 211 or coupled with the main conductive line 601 in the second conductive connection layer through the second conductive structure 212.

In some examples, the main conductive lines 501 in the first conductive connection layer extend along the second direction and are arranged along the third direction, and the main conductive lines 601 in the second conductive connection layer extend along the second direction and are arranged along the third direction. In addition, the two opposite ends of the main conductive line in the second direction may be respectively connected with two conductive structures extending along the first direction, one conductive structure may couple the main conductive line to the bit line 205, and the other conductive structure may couple the main conductive line to the sense amplifier 302, that is, an electrical signal transmitted to the sense amplifier 302 through the bit line 205 may be transmitted from one of the two opposite ends of the main conductive line in the second direction to the other end.

In some examples, the main conductive lines 501 in the first conductive connection layer and the main conductive lines 601 in the second conductive connection layer which are coupled with one sense amplifier 302 are arranged along the first direction.

In the examples of the present disclosure, the extension manner and the arrangement manner of the main conductive lines 501 in the first conductive connection layer and the extension manner and the arrangement manner of the main conductive lines 601 in the second conductive connection layer are similar to the extension manner and the arrangement manner of the plurality of bit lines 205, and the main conductive line 501 in the first conductive connection layer and the main conductive line 601 in the second conductive connection layer which are coupled with one sense amplifier 302 are arranged along the first direction, which is beneficial for disposing the main conductive lines without increasing the area of the memory device.

In some examples, the plurality of bit lines 205 includes a first bit line 2051 coupled with the first memory block Block1, here, taking two first bit lines 2051 adjacent in the third direction coupled with the first memory block Block1 as an example. The main conductive line in the coupling path between one of the two first bit lines 2051 adjacent in the third direction and a sense amplifier 302 is located in the first conductive connection layer 500, that is, it may be the main conductive line 501 in the first conductive connection layer; and the main conductive line in the coupling path between the other of the two first bit lines 2051 adjacent in the third direction and a sense amplifier 302 is located in the second conductive connection layer 600, that is, it may be the main conductive line 601 in the second conductive connection layer.

In some examples, the plurality of bit lines 205 further include a plurality of third bit lines 2053 coupled with the second memory block Block0, one first bit line 2051 and one third bit line 2053 are coupled with the same sense amplifier 302. And for the first bit line 2051 and the third bit line 2053 coupled with the same sense amplifier 302, the main conductive line in the coupling path between the first bit line 2051 and the sense amplifier 302 and the main conductive line in the coupling path between the third bit line 2053 and the sense amplifier 302 are located in different conductive connection layers. For example, when the main conductive line in the coupling path between the first bit line 2051 and the sense amplifier 302 is the main conductive line 501 in the first conductive connection layer, the main conductive line in the coupling path between the third bit line 2053 and the sense amplifier 302 is the main conductive line 601 in the second conductive connection layer; and when the main conductive line in the coupling path between the first bit line 2051 and the sense amplifier 302 is the main conductive line 601 in the second conductive connection layer, the main conductive line in the coupling path between the third bit line 2053 and the sense amplifier 302 is a main conductive line 501 in the first conductive connection layer.

In some examples, the plurality of bit lines 205 further include a plurality of second bit lines 2052 coupled with the first memory block Block1, the second bit lines 2052 are alternately stacked with the first bit lines 2051 in the third direction. The main conductive line in the coupling path between one of two second bit lines 2052 adjacent in the third direction and the sense amplifier 302 is located in the first conductive connection layer 500, and the main conductive line in the coupling path between the other of two second bit lines 2052 adjacent in the third direction and the sense amplifier 302 is located in the second conductive connection layer 600.

In some examples, the plurality of bit lines further includes a plurality of fourth bit lines 2054 coupled with the third memory block Block2, and one second bit line 2052 and one fourth bit line 2054 are coupled with the same sense amplifier 302.

In an example of the present disclosure, the first bit lines 2051 and the second bit lines 2052 coupled with the first memory block Block1 are alternately arranged in the third direction, and the conductive structure connected to the first bit line 2051 is close to the second memory block Block0, the conductive structure connected to the second bit line 2052 is close to the third memory block Block2, one first bit line 2051 and one third bit line 2053 which is coupled with the second memory block Block0 are coupled with the same sense amplifier 302, and one second bit line 2052 and one fourth bit line 2054 which is coupled with the third memory block Block2 are coupled with the same sense amplifier 302.

In some specific examples, the sense amplifier 302 coupled with the first bit line 2051 is stacked with the first memory block Block1 in the first direction, and the sense amplifier 302 coupled with the second bit line 2052 is stacked with the third memory block Block2 in the first direction, so that the extension dimension of other conductive lines in the coupling path between the bit lines 205 and the sense amplifiers 302 can be shortened as much as possible.

In some specific examples, taking the first memory block Block1 as the selected memory block in the read operation as an example, the third bit line 2053 coupled with the second memory block Block0 may be a complementary bit line of the first bit line 2051, and the fourth bit line 2054 coupled with the third memory block Block2 may be a complementary bit line of the second bit line 2052.

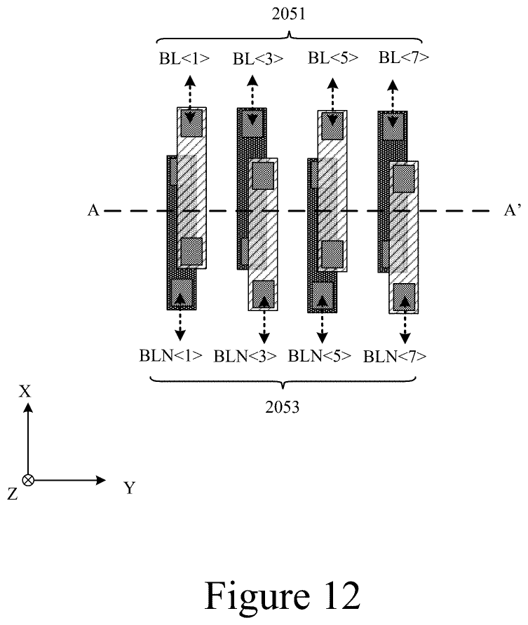

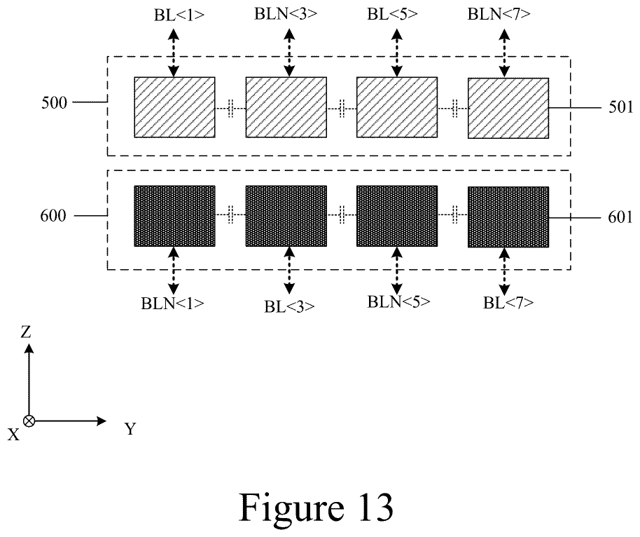

FIG. 12 and FIG. 13 are schematic diagrams of arrangement of the main conductive lines coupled with the first bit lines and the third bit lines according to a specific example, wherein FIG. 13 is a schematic cross-sectional view of FIG. 12 along line AA′, BL<1>, BL<3>, BL<5> and BL<7> are all the first bit lines 2051, and BLN<1>, BLN<3>, BLN<5> and BLN<7> are all the third bit lines 2053. For the first bit line 2051 and the third bit line 2053 coupled with the same sense amplifier 302, for example, BL<1> and BLN<1>, the main conductive line coupled with the first bit line 2051 and the main conductive line coupled with the third bit line 2053 are located in different conductive connection layers; and for two first bit lines 2051 adjacent in the third direction, the main conductive line coupled with one first bit lines 2051 and the main conductive line coupled with the other one first bit line 2051 are located in different conductive connection layers, for example, the main conductive line coupled with BL<1> and the main conductive line coupled with BLN<1> are respectively located in the first conductive connection layer 500 and the second conductive connection layer 600; one main conductive line coupled with the first bit line 2051 and one main conductive line coupled with the third bit line 2053 are located in the same conductive connection layer and are adjacent in the third direction, for example, the main conductive line coupled with BL<3> and the main conductive line coupled with BLN<1> are both located in the second conductive connection layer 600, and BL<1> coupled with the same sense amplifier with BLN<1> are adjacent to BL<3>in the third direction, then parasitic capacitance may be generated between the main conductive line coupled with BL<3> and the main conductive line coupled with BLN<1>.

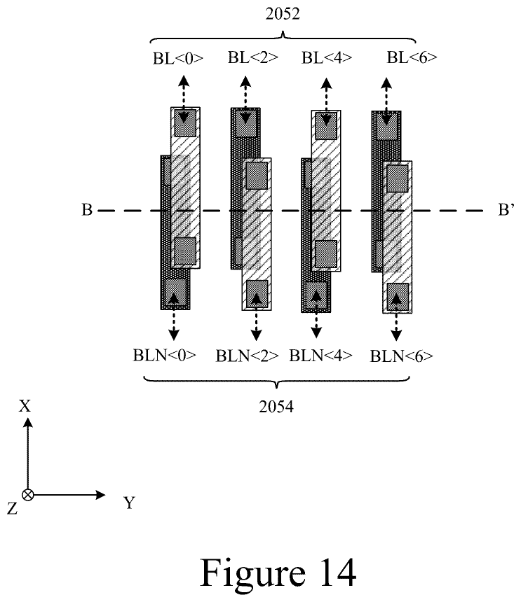

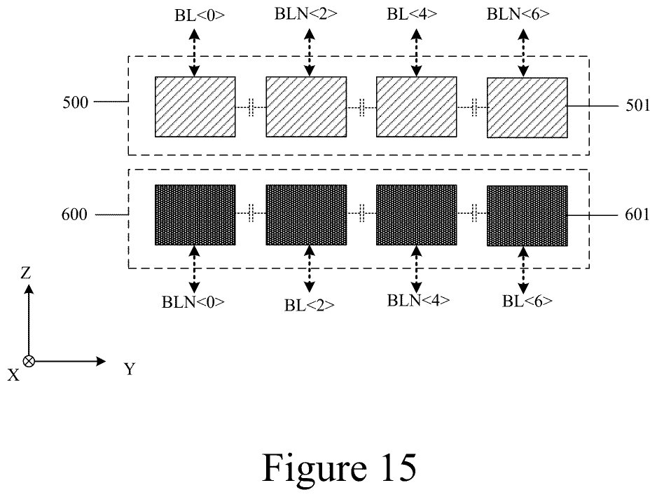

FIG. 14 and FIG. 15 are schematic diagrams of arrangements of the main conductive lines coupled with the first bit lines and the third bit lines provided by a specific example, wherein FIG. 15 is a schematic cross-sectional view of FIG. 14 along line BB′, BL<0>, BL<2>, BL<4>, and BL<6> are all the second bit lines 2052, and BLN<0>, BLN<2>, BLN<4>, and BLN<6> are all the fourth bit lines 2054. For the second bit line 2052 and the fourth bit line 2054 coupled with the same sense amplifier 302, for example, BL<0>and BLN<0>, the main conductive line coupled with the second bit line 2052 and the main conductive line coupled with the fourth bit line 2054 are located in different conductive connection layers; for two second bit lines 2052 adjacent in the third direction, the main conductive line coupled with one second bit line 2052 and the main conductive line coupled with the other second bit line 2052 are located in different conductive connection layers, for example, the main conductive line coupled with BL<0> and the main conductive line coupled with BL<2> are respectively located in the first conductive connection layer 500 and the second conductive connection layer 600; one main conductive line coupled with the second bit line 2052 and one main conductive line coupled with the fourth bit line 2054 are located in the same conductive connection layer and adjacent in the third direction, for example, the main conductive line coupled with BL<2> and the main conductive line coupled with BLN<0> are both located in the second conductive connection layer 600 and are adjacent in the third direction, then parasitic capacitance may be generated between the main conductive line coupled with BL<2> and the main conductive line coupled with BLN<0>.

Based on the above specific example, in an example of the present disclosure, the main conductive line in the coupling path between the third bit line (e.g., BLN<x>) coupled with the same sense amplifier as one first bit line (e.g., BL<x>) and the sense amplifier, and the main conductive line in the coupling path between another first bit line (e.g., BL<x+2>) and the sense amplifier may be located in the same conductive connection layer and are adjacent in the third direction, thus the parasitic capacitance between the first bit line (BL<x>) and the second bit line (e.g., BL<x+1>) that are adjacent may be compensated by using the parasitic capacitance between the main conductive line coupled with the another first bit line (BL<x+2>) and the main conductive line coupled with the third bit line (BLN<x>). Similarly, the main conductive line in the coupling path between the fourth bit line (e.g., BLN<x+1>) coupled with the same sense amplifier as one second bit line (e.g., BL<x+1>) and the sense amplifier, and the main conductive line in the coupling path between another second bit line (e.g., BL<x+3>) and the sense amplifier may be located in the same conductive connection layer and are adjacent in the third direction, thus the parasitic capacitance between the first bit line (BL<x>) and second bit line (BL<x+1>) that are adjacent may be compensated using the parasitic capacitance between the main conductive line coupled with the another second bit line (BL<x+3>) and the main conductive line coupled with the fourth bit line (BLN<x+1>). Thus, the memory device provided by the present disclosure can reduce the degree of sensing margin decrease due to parasitic capacitance between adjacent bit lines, and has higher reliability.

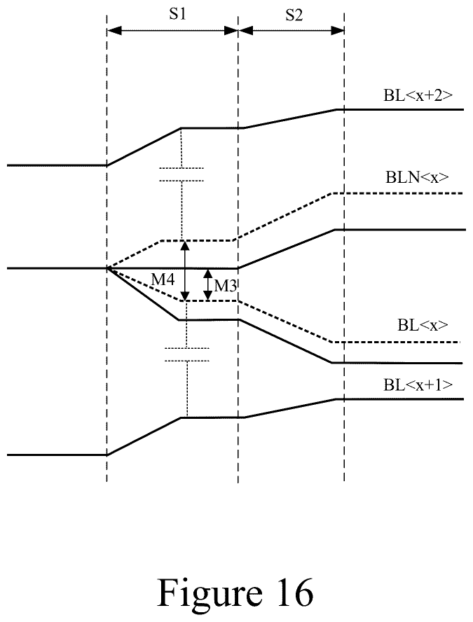

FIG. 16 is a third schematic diagram of the voltages on bit lines in a read operation provided by an example of the present disclosure. Taking the data stored in the selected memory cell coupled with BL<x>being “0” and both the data stored in the selected memory cell coupled with BL<x+1> and the data stored in the selected memory cell coupled with BL<x+2> being “1” as an example, in the charge sharing stage S1, the voltage on BL<x> decreases, and both the voltage on BL<x+1> and the voltage on BL<x+2> increase. As the coupling effect caused by parasitic capacitance between BL<x> and BL<x+1> adjacent in the third direction may suppress the decrease of the voltage on BL<x>, causing the degree of voltage drop on BL<x> to decrease, the sensing margin between BL<x> and BLN<x> may be compressed to M3. In the memory device provided in this disclosure, as the main conductive line in the coupling path between BLN<x> and the sense amplifier and the main conductive line in the coupling path between BL<x+2> and the sense amplifier being located in the same conductive connection layer and being adjacent in the third direction, the coupling effect caused by the parasitic capacitance between the two main conductive lines can cause the voltage on BL<x> to increase, thereby compensating the sensing margin between BL<x> and BLN<x> to M4, so that there is still a large sensing margin between BL<x> and BLN<x>. In the sensing stage S2, the sense amplifier can still amplify the voltage difference between BL<x> and BLN<x> to the extent that the data stored in the memory cell coupled with BL<x> can be correctly read out, thereby improving the reliability of the memory device.

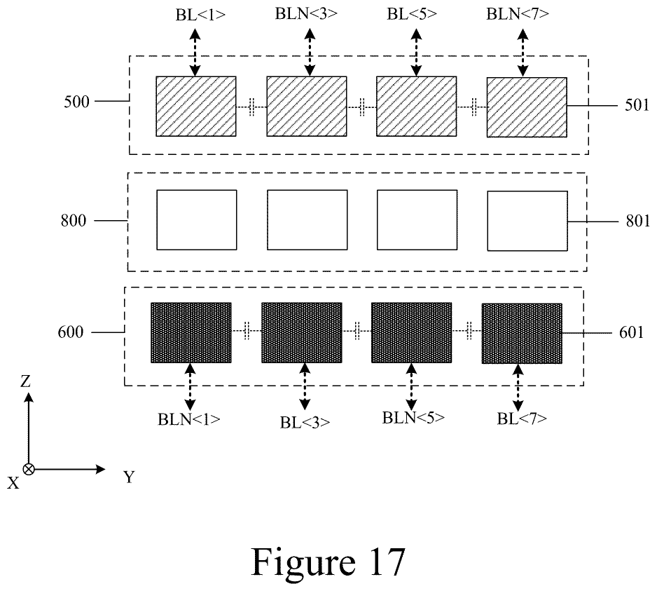

In some examples, FIG. 17 is a second schematic diagram of the arrangement of the main conductive lines coupled with the first bit lines and the third bit lines provided by an example of the present disclosure. The first semiconductor structure 200 further includes: a third conductive connection layer 800 located between the first conductive connection layer 500 and the second conductive connection layer 600; a coupling path between one of the two bit lines coupled with the sense amplifier and the sense amplifier further includes a conductive line 801 in the third conductive connection layer, and a coupling path between the other of the two bit lines coupled with the sense amplifier and the sense amplifier further includes the conductive line 801 in the third conductive connection layer. Here, the conductive line 801 of the third conductive connection layer may function as a jumper. Specifically, when the parasitic capacitance between adjacent main conductive lines 501 in the first conductive connection layer or the parasitic capacitance between adjacent main conductive lines 601 in the second conductive connection layer is configured to compensate the parasitic capacitance between adjacent bit lines, the parasitic capacitance between the main conductive lines may be insufficient to compensate the parasitic capacitance between the adjacent bit lines due to the limited length of the main conductive lines, in such case, the parasitic capacitance between conductive lines 801 in the third conductive connection layer can be configured to compensate the parasitic capacitance between adjacent bit lines. In addition, a part of the conductive lines in the third conductive connection layer 800 may also play a role of signal shielding, to avoid a larger parasitic capacitance to be generated between a main conductive line 501 in the first conductive connection layer and a conductive line 601 in the second conductive connection layer.

Based on a concept similar to that of the above memory device, the present disclosure further provides a memory system, including at least one memory device in any of the above examples and a controller coupled with the memory device and configured to control the memory device. For composition and functions of the memory system, reference may be made to the description of FIG. 1 in the foregoing examples, and details thereof are not described herein again.

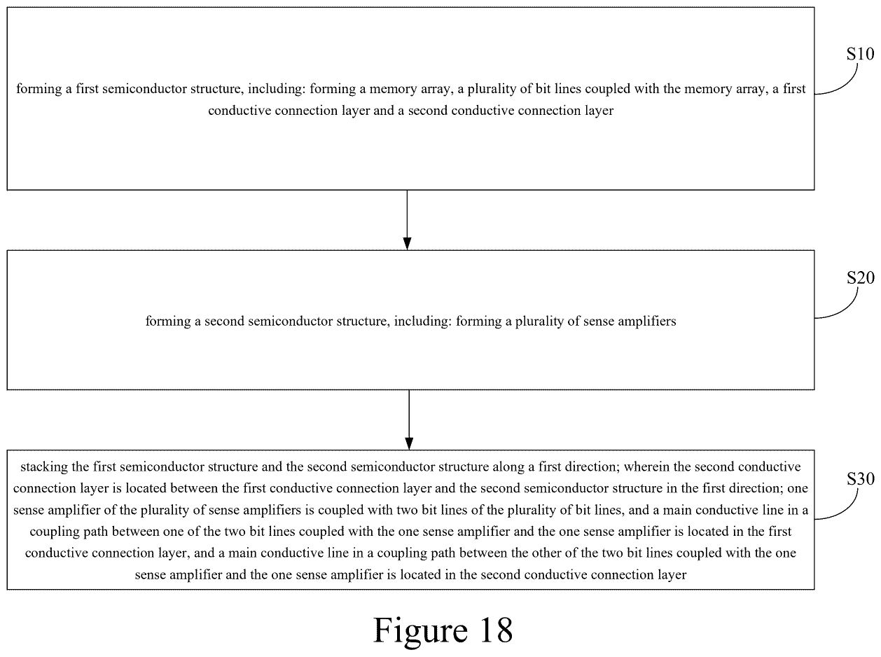

Based on a concept similar to the above memory device, the present disclosure further provides a forming method of the memory device, FIG. 18 is a schematic flowchart of a forming method of the memory device provided by an example of the present disclosure, and the forming method of the memory device includes the following operations:
S10: forming a first semiconductor structure, including: forming a memory array, a plurality of bit lines coupled with the memory array, a first conductive connection layer and a second conductive connection layer;
S20: forming a second semiconductor structure, including: forming a plurality of sense amplifiers;
S30: stacking the first semiconductor structure and the second semiconductor structure along a first direction; wherein: the second conductive connection layer is located between the first conductive connection layer and the second semiconductor structure in the first direction; sense amplifier is coupled with two bit lines, and a main conductive line in a coupling path between one of the two bit lines coupled with the sense amplifier and the sense amplifier is located in the first conductive connection layer, and a main conductive line in a coupling path between the other of the two bit lines coupled with the sense amplifier and the sense amplifier is located in the second conductive connection layer.

In an example of the present disclosure, an extension dimension of the main conductive line in the coupling path in a direction perpendicular to the first direction is larger than an extension dimension of other conductive lines in the coupling path in the direction perpendicular to the first direction.

In some examples, the plurality of bit lines are located between the memory array and the first conductive connection layer in the first direction; the plurality of bit lines extend along the second direction and are arranged along the second direction and the third direction; and the second direction is perpendicular to the third direction, and both the second direction and the third direction are perpendicular to the first direction.

In some examples, forming the memory array includes: forming a first memory block; wherein forming the plurality of bit lines includes: forming a plurality of first bit lines coupled with the first memory block; wherein a main conductive line in a coupling path between one of two first bit lines adjacent in the third direction and a sense amplifier is located in the first conductive connection layer, and a main conductive line in a coupling path between the other of the two first bit lines adjacent in the third direction and a sense amplifier is located in the second conductive connection layer.

In some examples, forming the plurality of bit lines further includes: forming a plurality of second bit lines coupled with the first memory block; wherein the second bit lines and the first bit lines are alternately arranged in a third direction; a main conductive line in a coupling path between one of two second bit lines adjacent in the third direction and a sense amplifier is located in the first conductive connection layer, and a main conductive line in a coupling path between the other of the two second bit lines adjacent in the third direction and a sense amplifier is located in the second conductive connection layer.

In some examples, forming the memory array further includes: forming a second memory block and a third memory block; wherein the first memory block is located between the second memory block and the third memory block in the second direction; the plurality of bit lines further include a plurality of third bit lines coupled with the second memory block and a plurality of fourth bit lines coupled with the third memory block; one first bit line and one third bit line are coupled with the same sense amplifier; and one second bit line and one fourth bit line are coupled with the same sense amplifier.

In some examples, forming the first semiconductor structure further includes: before forming the first conductive connection layer and the second conductive connection layer, forming a first conductive structure extending along the first direction and a second conductive structure extending along the first direction, wherein one of two opposite ends of the first conductive structure along the first direction is connected with one bit line, and one of two opposite ends of the second conductive structure along the first direction is connected with one bit line; and after forming the first conductive connection layer and the second conductive connection layer, the other of the two opposite ends of the first conductive structure along the first direction is coupled with a main conductive line in the first conductive connection layer, and the other of the two opposite ends of the second conductive structure along the first direction is coupled with a main conductive line in the second conductive connection layer.

In some examples, forming the first semiconductor structure further includes: forming a third conductive connection layer; wherein the third conductive connection layer is located between the first conductive connection layer and the second conductive connection layer; a coupling path between one of two bit lines coupled with a sense amplifier and the sense amplifier further includes a conductive line in the third conductive connection layer, and the coupling path between the other of the two bit lines coupled with the sense amplifier and the sense amplifier further includes a conductive line in the third conductive connection layer.

In some examples, the forming method of the memory device further includes: forming a bonding layer between the first semiconductor structure and the second semiconductor structure; wherein the bonding layer includes a bonding structure; the bonding structure is coupled with a main conductive line in the first conductive connection layer, or the bonding structure is coupled with a main conductive line in the second conductive connection layer; and a coupling path between a bit line and a sense amplifier includes the bonding structure.

In some examples, forming the second semiconductor structure further includes: forming a fourth conductive connection layer; wherein: the fourth conductive layer is located on one side of the plurality of sense amplifiers in the first direction; a conductive line in the fourth conductive layer is coupled with a sense amplifier, and a bonding structure is coupled with a conductive line in the fourth conductive connection layer; and a coupling path between bit line and a sense amplifier includes a conductive line in the fourth conductive connection layer.

In some examples, forming the memory array includes: forming memory cells arranged in an array along the second direction and the third direction; wherein the memory cells include transistor structures and capacitor structures coupled with the transistor structures.

The features disclosed in several device examples provided by the present disclosure may be arbitrarily combined without conflict to obtain new device examples.

The methods disclosed in the several method examples provided by the present disclosure may be arbitrarily combined without conflict to obtain new method examples.

The above is only specific implementations of the present disclosure, but the protection scope of the present disclosure is not limited thereto. Any skilled person familiar with the technical field can easily think of changes or replacements within the technical scope disclosed in the present disclosure, which should be included in the protection scope of the present disclosure.

What is claimed is:

1. A memory device comprising a first semiconductor structure and a second semiconductor structure stacked along a first direction, wherein
the first semiconductor structure comprises a memory array, a plurality of bit lines coupled with the memory array, a first conductive connection layer, and a second conductive connection layer; wherein the second conductive connection layer is located between the first conductive connection layer and the second semiconductor structure in the first direction; and
the second semiconductor structure comprises a plurality of sense amplifiers; one sense amplifier of the plurality of sense amplifiers is coupled with two bit lines of the plurality of bit lines, and a main conductive line in a coupling path between one of the two bit lines coupled with the one sense amplifier and the one sense amplifier is located in the first conductive connection layer, and a main conductive line in a coupling path between the other of the two bit lines coupled with the one sense amplifier and the one sense amplifier is located in the second conductive connection layer; and an extension dimension of a main conductive line in the coupling path in a direction perpendicular to the first direction is larger than extension dimensions of other conductive lines in the coupling path in the direction perpendicular to the first direction.

2. The memory device of claim 1, wherein the plurality of bit lines are located between the memory array and the first conductive connection layer in the first direction; the plurality of bit lines extend along a second direction and are arranged along the second direction and a third direction; and wherein the second direction is perpendicular to the third direction, and both the second direction and the third direction are perpendicular to the first direction; and
the memory array comprises a first memory block; the plurality of bit lines comprise a plurality of first bit lines coupled with the first memory block; and
a main conductive line in a coupling path between one of two first bit lines adjacent in the third direction among the plurality of first bit lines and a sense amplifier is located in the first conductive connection layer, and a main conductive line in a coupling path between the other of the two first bit lines adjacent in the third direction and a sense amplifier is located in the second conductive connection layer.

3. The memory device of claim 1, wherein the main conductive line in the first conductive connection layer and the main conductive line in the second conductive connection layer which are coupled with the one sense amplifier are arranged along the first direction.

4. The memory device of claim 2, wherein the plurality of bit lines further comprise a plurality of second bit lines coupled with the first memory block; and the plurality of second bit lines and the plurality of first bit lines are alternately arranged in the third direction; and
a main conductive line in a coupling path between one of two second bit lines adjacent in the third direction among the plurality of second bit lines and a sense amplifier is located in the first conductive connection layer, and a main conductive line in a coupling path between the other of the two second bit lines adjacent in the third direction and a sense amplifier is located in the second conductive connection layer.

5. The memory device of claim 4, wherein the memory array further comprises:
a second memory block and a third memory block; wherein the first memory block is located between the second memory block and the third memory block in the second direction; the plurality of bit lines further comprise a plurality of third bit lines coupled with the second memory block and a plurality of fourth bit lines coupled with the third memory block; one first bit line of the plurality of first bit lines and one third bit line of the plurality of third bit lines are coupled with the same sense amplifier; and one second bit line of the plurality of second bit lines and one fourth bit line of the plurality of fourth bit lines are coupled with the same sense amplifier.

6. The memory device of claim 5, wherein a sense amplifier coupled with the first bit line is stacked with the first memory block in the first direction, and a sense amplifier coupled with the second bit line is stacked with the third memory block in the first direction.

7. The memory device of claim 1, wherein the first semiconductor structure further comprises:
a first conductive structure extending along the first direction, wherein one of two opposite ends of the first conductive structure along the first direction is connected with the bit line, and the other of the two opposite ends of the first conductive structure along the first direction is coupled with the main conductive line in the first conductive connection layer; and
a second conductive structure extending along the first direction, wherein one of two opposite ends of the second conductive structure along the first direction is connected with the bit line, and the other of the two opposite ends of the second conductive structure along the first direction is coupled with the main conductive line in the second conductive connection layer.

8. The memory device of claim 1, wherein the first semiconductor structure further comprises:
a third conductive connection layer located between the first conductive connection layer and the second conductive connection layer; and
a coupling path between one of the two bit lines coupled with the one sense amplifier and the one sense amplifier further comprises a conductive line in the third conductive connection layer, and a coupling path between the other of the two bit lines coupled with the one sense amplifier and the one sense amplifier further comprises a conductive line in the third conductive connection layer.

9. The memory device of claim 2, further comprising:
a bonding layer located between the first semiconductor structure and the second semiconductor structure, wherein the bonding layer comprises a bonding structure, and the bonding structure is coupled with a main conductive line in the first conductive connection layer, or the bonding structure is coupled with a main conductive line in the second conductive connection layer, and a coupling path between the bit line and the sense amplifier comprises the bonding structure.

10. The memory device of claim 9, wherein the second semiconductor structure further comprises:
a fourth conductive connection layer located between the plurality of sense amplifiers and the bonding layer, wherein the bonding structure is coupled with a conductive line in the fourth conductive connection layer, and the conductive line in the fourth conductive connection layer is coupled with the sense amplifier; and
a coupling path between the bit line and the sense amplifier comprises the conductive line in the fourth conductive connection layer.

11. The memory device according to claim 2, wherein the memory array comprises:
memory cells arranged in an array along the second direction and the third direction, wherein the memory cell comprises a transistor structure and a capacitor structure coupled with the transistor structure.

12. A memory system comprising:
at least one memory device; and
a controller coupled with the at least one memory device and configured to control the at least one memory device, wherein
the memory device comprises a first semiconductor structure and a second semiconductor structure stacked along a first direction, wherein
the first semiconductor structure comprises a memory array, a plurality of bit lines coupled with the memory array, a first conductive connection layer, and a second conductive connection layer; wherein the second conductive connection layer is located between the first conductive connection layer and the second semiconductor structure in the first direction; and
the second semiconductor structure comprises a plurality of sense amplifiers; one sense amplifier of the plurality of sense amplifiers is coupled with two bit lines of the plurality of bit lines, and a main conductive line in a coupling path between one of the two bit lines coupled with the one sense amplifier and the one sense amplifier is located in the first conductive connection layer, and a main conductive line in a coupling path between the other of the two bit lines coupled with the one sense amplifier and the one sense amplifier is located in the second conductive connection layer; and an extension dimension of a main conductive line in the coupling path in a direction perpendicular to the first direction is larger than extension dimensions of other conductive lines in the coupling path in the direction perpendicular to the first direction.

13. A forming method of a memory device comprising:
forming a first semiconductor structure, comprising: forming a memory array, a plurality of bit lines coupled with the memory array, a first conductive connection layer, and a second conductive connection layer;
forming a second semiconductor structure, comprising: forming a plurality of sense amplifiers; and
stacking the first semiconductor structure and the second semiconductor structure along a first direction; wherein the second conductive connection layer is located between the first conductive connection layer and the second semiconductor structure in the first direction; one sense amplifier of the plurality of sense amplifiers is coupled with two bit lines of the plurality of bit lines, and a main conductive line in a coupling path between one of the two bit lines coupled with the one sense amplifier and the one sense amplifier is located in the first conductive connection layer, and a main conductive line in a coupling path between the other of the two bit lines coupled with the one sense amplifier and the one sense amplifier is located in the second conductive connection layer; and an extension dimension of a main conductive line in the coupling path in a direction perpendicular to the first direction is larger than extension dimensions of other conductive lines in the coupling path in the direction perpendicular to the first direction.

14. The forming method of the memory device of claim 13, wherein the plurality of bit lines are located between the memory array and the first conductive connection layer in the first direction; the plurality of bit lines extend along a second direction and are arranged along the second direction and a third direction; and wherein the second direction is perpendicular to the third direction, and both the second direction and the third direction are perpendicular to the first direction; wherein:
forming the memory array comprises: forming a first memory block; and
forming the plurality of bit lines comprises: forming a plurality of first bit lines coupled with the first memory block, wherein a main conductive line in a coupling path between one of two first bit lines adjacent in the third direction among the plurality of first bit lines and a sense amplifier is located in the first conductive connection layer, and a main conductive line in a coupling path between the other of the two first bit lines adjacent in the third direction and a sense amplifier is located in the second conductive connection layer.

15. The forming method of the memory device of claim 14, wherein forming the plurality of bit lines further comprises:
forming a plurality of second bit lines coupled with the first memory block, wherein the plurality of second bit lines and the plurality of first bit lines are alternately arranged in the third direction; and a main conductive line in a coupling path between one of two second bit lines adjacent in the third direction among the plurality of second bit lines and a sense amplifier is located in the first conductive connection layer, and a main conductive line in a coupling path between the other of the two second bit lines adjacent in the third direction and a sense amplifier is located in the second conductive connection layer.

16. The forming method of the memory device of claim 15, wherein forming the memory array further comprises:
forming a second memory block and a third memory block; wherein the first memory block is located between the second memory block and the third memory block in the second direction; the plurality of bit lines further comprise a plurality of third bit lines coupled with the second memory block and a plurality of fourth bit lines coupled with the third memory block; one first bit line of the plurality of first bit lines and one third bit line of the plurality of third bit lines are coupled with the same sense amplifier; and one second bit line of the plurality of second bit lines and one fourth bit line of the plurality of fourth bit lines are coupled with the same sense amplifier.

17. The forming method of the memory device of claim 13, wherein forming the first semiconductor structure further comprises:
forming a first conductive structure extending along the first direction and a second conductive structure extending along the first direction before forming the first conductive connection layer and the second conductive connection layer, wherein one of two opposite ends of the first conductive structure along the first direction is connected with the bit line, and one of the two opposite ends of the second conductive structure along the first direction is connected with the bit line; wherein
after the first conductive connection layer and the second conductive connection layer are formed, the other of the two opposite ends of the first conductive structure along the first direction is coupled with the main conductive line in the first conductive connection layer, and the other of the two opposite ends of the second conductive structure along the first direction is coupled with the main conductive line in the second conductive connection layer.

18. The forming method of the memory device of claim 13, wherein forming the first semiconductor structure further comprises:
forming a third conductive connection layer, wherein the third conductive connection layer is located between the first conductive connection layer and the second conductive connection layer; and a coupling path between one of the two bit lines coupled with the one sense amplifier and the one sense amplifier further comprises a conductive line in the third conductive connection layer, and a coupling path between the other of the two bit lines coupled with the one sense amplifier and the one sense amplifier further comprises a conductive line in the third conductive connection layer.

19. The forming method of the memory device of claim 13, further comprising:
forming a bonding layer between the first semiconductor structure and the second semiconductor structure; wherein the bonding layer comprises a bonding structure, wherein the bonding structure is coupled with a main conductive line in the first conductive connection layer, or the bonding structure is coupled with a main conductive line in the second conductive connection layer, and a coupling path between the bit line and the sense amplifier comprises the bonding structure.

20. The forming method of the memory device of claim 19, wherein forming the second semiconductor structure further comprises:
forming a fourth conductive connection layer; wherein the fourth conductive connection layer is located on one side of the plurality of sense amplifiers in the first direction; a conductive line in the fourth conductive connection layer is coupled with a sense amplifier, and the bonding structure is coupled with the conductive line in the fourth conductive connection layer; and a coupling path between the bit line and the sense amplifier comprises the conductive line in the fourth conductive connection layer.
